(19) United States
(12) Patent Application Publication
(10) Pub. No.: US 2025/0230595 A1
(43) Pub. Date: Jul. 17, 2025

(54) WASHING MACHINE AND CONTROLLING METHOD FOR SAME

(71) Applicant: SAMSUNG ELECTRONICS CO., LTD., Suwon-si (KR)

(72) Inventors: Jaepoong LEE, Suwon-si (KR); Sukwoo PARK, Suwon-si (KR); Seunghoon KIM, Suwon-si (KR)

(73) Assignee: SAMSUNG ELECTRONICS CO., LTD., Suwon-si (KR)

(21) Appl. No.: 19/095,401

(22) Filed: Mar. 31, 2025

Related U.S. Application Data
(63) Continuation of application No. PCT/KR2023/015435, filed on Oct. 6, 2023.

(30) Foreign Application Priority Data
Oct. 31, 2022 (KR) 10-2022-0142851

(51) Int. Cl. D06F 34/18; D06F 23/06; D06F 33/34; D06F 33/42; D06F 34/16; D06F 34/28; D06F 37/30; D06F 39/08; D06F 103/04; D06F 103/06; D06F 103/18; D06F 103/26; D06F 103/46; D06F 105/02; D06F 105/08; D06F 105/46; D06F 105/58; G01R 19/10

(52) U.S. Cl. CPC D06F 34/18; D06F 23/06; D06F 33/34; D06F 33/42; D06F 34/16; D06F 34/28; D06F 37/304; D06F 39/087; D06F 39/088; G01R 19/10; D06F 2103/04; D06F 2103/06; D06F 2103/18; D06F 2103/26; D06F 2103/46; D06F 2105/02; D06F 2105/08; D06F 2105/46; D06F 2105/58

(57) ABSTRACT

A washing machine including a drum that is rotatable while accommodated inside a tub; a driving circuit that supplies a driving current to a motor to rotate the drum; a current sensor that senses the driving current; and a controller that controls the drum, the driving circuit, and the current sensor. The controller is enabled to determine whether laundry in the drum contains a waterproof item based on a weight of the laundry and a difference value between a first driving current sensed by the current sensor before a washing cycle and a second driving current sensed by the current sensor after the washing cycle.

### CROSS-REFERENCE TO RELATED APPLICATION

This application is a continuation application is a continuation application, under 35 U.S.C. § 111(a), of international application No. PCT/KR2023/015435, filed Oct. 6, 2023, which claims priority under 35 U. S. C. § 119 to Korean Patent Application No. 10-2022-0142851, filed Oct. 31, 2022, the disclosures of which are incorporated herein by reference in their entireties.

### TECHNICAL FIELD

The present disclosure relates to a washing machine and a control method thereof.

### BACKGROUND ART

In general, a washing machine is a device that includes a tub that stores water and a drum that is installed rotatably within the tub, and laundry may be washed by rotating the drum containing water and laundry within the tub.

The washing machine may perform a washing process for washing laundry, a rinsing process for rinsing washed laundry, and a spin-drying process for spin-drying laundry.

In particular, the spin-drying process may separate water absorbed in the laundry from the laundry by rotating the drum containing the laundry at approximately 1000 revolutions per minute (rpm).

Recently, waterproof bedding has been widely used for pest control. In addition, due to the increase in outdoor activities, clothes formed of waterproof cloth have also been widely used.

Waterproof bedding or clothes formed of waterproof cloth (hereinafter referred to as “waterproof item”) may damage the washing machine during the spin-drying operation. For example, when water is drained after washing and/or rinsing, the waterproof cloth may trap water like a bag. When the drum rotates at a high speed for spin-drying after draining, the movement of the water trapped by the waterproof cloth may cause weight imbalance. The drum and the tub may vibrate greatly due to the weight imbalance, which may damage the washing machine.

### DISCLOSURE

### Technical Problem

The present disclosure is directed to providing a washing machine capable of determining whether laundry in a drum of the washing machine includes a waterproof cloth, and a control method thereof.

### Technical Solution

One aspect of the present disclosure provides a washing machine including: a drum that is rotatable while accommodated inside a tub; a driving circuit configured to supply a driving current to a motor to rotate the drum; a current sensor configured to detect the driving current; and a controller configured to control the drum, the driving circuit, and the current sensor. The controller is configured to determine whether laundry in the drum contains a waterproof item based on a weight value of the laundry and a difference value between a first driving current value detected by the current sensor before a washing process and a second driving current value detected by the current sensor after the washing process.

The controller may be configured to determine that the laundry in the drum contains no waterproof item based on the difference value being less than a reference value; and configured to determine that laundry in the drum contains the waterproof item based on the difference value being greater than or equal to the reference value.

The controller may be configured to determine the reference value based on the weight value of the laundry.

The reference value may be proportional to a weight of the laundry.

The controller may be configured to perform pre-water supply and pre-draining before measuring the first driving current value.

The washing machine may further include a water level sensor configured to detect a water level of the tub. The controller may be configured to perform additional water supply to a reference water level in response to the water level of the tub being less than the reference water level after the pre-water supply.

The controller may be configured to measure the second driving current value after the washing process and draining are completed.

The controller may be configured to measure the second driving current value multiple times and configured to determine whether or not the waterproof item is contained in the laundry in the drum based on each of the measured second driving current values.

The washing machine may further include a display to display washing settings and washing operation information. The controller may be configured to control the display portion to display a notification to a user in response to a determination that the waterproof item is contained in the laundry in the drum.

Another aspect of the present disclosure provides a control method of a washing machine including: measuring a first driving current value while rotating a drum before a washing process; measuring a second driving current value while rotating the drum after the washing process; and determining whether or not a waterproof item is contained based on a weight value of laundry and a difference value between the first driving current value and the second driving current value.

Determining whether or not the waterproof item is contained may include determining that the waterproof item is not contained in response to the difference value being less than a reference value; and determining that the waterproof item is contained in response to the difference value being greater than or equal to the reference value.

Determining whether or not the waterproof item is contained may include determining the reference value based on the weight value of the laundry.

The reference value may be proportional to a weight of the laundry.

Measuring the first driving current value may include performing pre-water supply and pre-draining before measuring the first driving current value.

Measuring the first driving current value may include performing additional water supply to a reference water level in response to a water level of a tub being less than the reference water level after the pre-water supply.

Measuring the second driving current value may include measuring the second driving current value after the washing process and draining are completed.

The control method of the washing machine may include measuring the second driving current value multiple times. Determining whether the waterproof item is contained in the laundry in the drum may include determining whether the waterproof item is contained in the laundry in the drum based on each of the measured second driving current values.

The control method of the washing machine may further include displaying a notification to a user in response to a determination that the waterproof item is contained in the laundry in the drum.

### Advantageous Effects

It is possible to determine whether laundry in a drum of a washing machine includes a waterproof cloth.

### DESCRIPTION OF DRAWINGS

FIG. 1 illustrates an appearance of a washing machine according to one embodiment.

FIG. 2 illustrates a side cross-section of the washing machine according to one embodiment.

FIG. 3 is a block diagram illustrating a configuration of the washing machine according to one embodiment.

FIG. 4 illustrates an example of a driving circuit included in the washing machine according to one embodiment.

FIG. 5 illustrates an example of a driving controller included in the washing machine according to one embodiment.

FIG. 6 illustrates an example of a washing cycle of the washing machine according to one embodiment.

FIG. 7 is a flowchart illustrating a method for the washing machine according to one embodiment to detect a first driving current before performing the washing cycle.

FIG. 8 is a flowchart illustrating a method for the washing machine according to one embodiment to detect a second driving current and determine whether a waterproof cloth is included.

### MODES OF THE INVENTION

Embodiments described in the disclosure and configurations shown in the drawings are merely examples of the embodiments of the disclosure, and may be modified in various different ways at the time of filing of the present application to replace the embodiments and drawings of the disclosure

[symbol]

It will be understood that when an element is referred to as being “connected” another element, it can be directly or indirectly connected to the other element, wherein the indirect connection includes “connection via a wireless communication network”

[symbol]

Also, the terms used herein are used to describe the embodiments and are not intended to limit and/or restrict the disclosure. The singular forms “a,” “an” and “the” are intended to include the plural forms as well, unless the context clearly indicates otherwise. In this disclosure, the terms “including”, “having”, and the like are used to specify features, numbers, steps, operations, elements, components, or combinations thereof, but do not preclude the presence or addition of one or more of the features, numbers, steps, operations, elements, components, or combinations thereof.

It will be understood that, although the terms first, second, third, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

In the following description, terms such as “unit”, “part”, “block”, “member”, and “module” indicate a unit for processing at least one function or operation. For example, those terms may refer to at least one process processed by at least one hardware such as Field Programmable Gate Array (FPGA), Application Specific Integrated Circuit (ASIC), at least one software stored in a memory or a processor.

An identification code is used for the convenience of the description but is not intended to illustrate the order of each step. The each step may be implemented in the order different from the illustrated order unless the context clearly indicates otherwise.

Reference will now be made in detail to embodiments of the disclosure, examples of which are illustrated in the accompanying drawings.

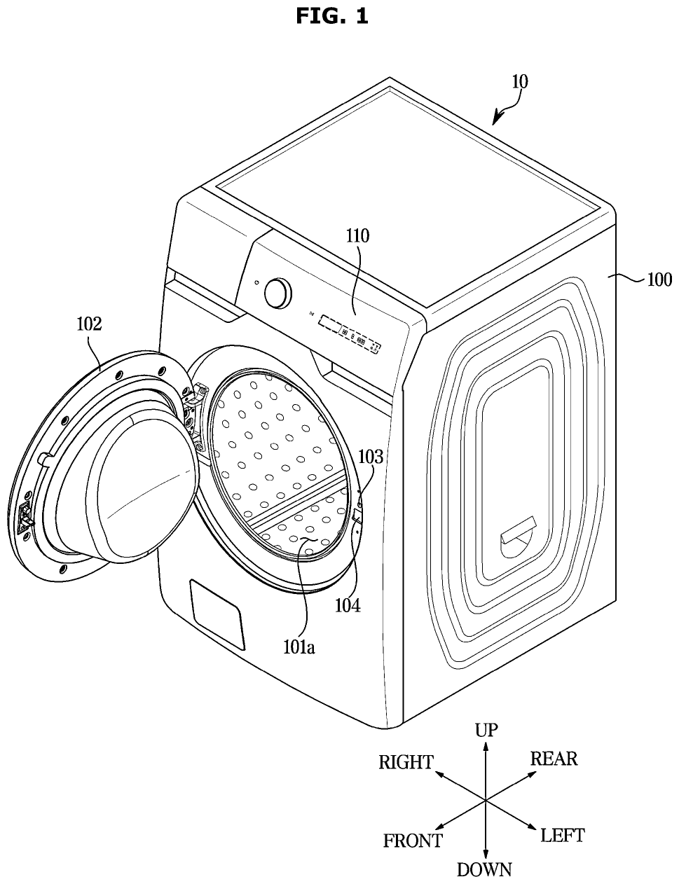

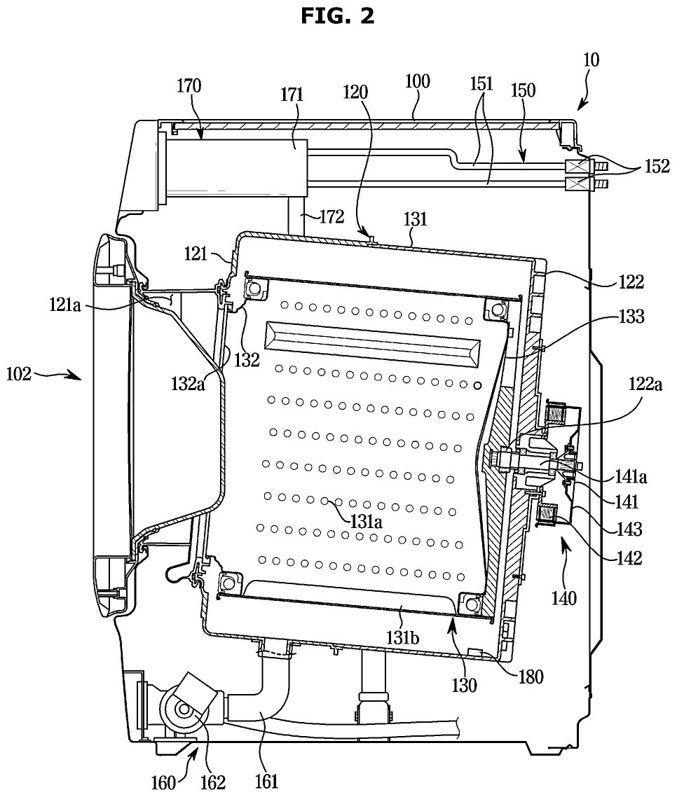

FIG. 1 illustrates an appearance of a washing machine according to one embodiment, and FIG. 2 illustrates a side cross-section of the washing machine according to one embodiment.

A configuration of a washing machine 10 is described with reference to FIGS. 1 and 2.

The washing machine 10 according to one embodiment may be a drum-type washing machine that washes laundry by rotating a drum 130 to repeatedly raise and lower laundry.

Referring to FIGS. 1 and 2, the washing machine 10 may include a cabinet 100 and a door 102 provided at the front of the cabinet 100. An inlet 101a for inserting or taking out laundry may be provided at the center of the front of the cabinet 100. The door 102 may be configured to open or close the inlet 101a. One side of the door 102 may be mounted to be rotatable by a hinge. The closure of the inlet 101a by the door 102 may be detected by a door switch 103. When the inlet 101a is closed and the washing machine 10 is in operation, the door 102 may be locked by a door lock 104.

In addition, the washing machine 10 may include a control panel 110, a tub 120, the drum 130, a driving portion 140, a water supply device 150, a drainage device 160, a detergent supply portion 170, and a water level sensor 180.

The control panel 110 including an inputter 112 configured to obtain a user input and a display portion 111 provided to display operation information of the washing machine 10 may be provided on an upper portion of a front surface of the cabinet 100. The control panel 110 may provide a user interface for interaction between a user and the washing machine 10.

The tub 120 may be disposed inside the cabinet 100 and may accommodate water for washing and/or rinsing. The tub 120 may include a tub front part 121 in which an opening 121a is formed on a front surface, and a tub rear part 122 having a cylindrical shape in which a rear surface is closed. The opening 121a for putting laundry into the drum 130 or taking laundry out from the drum 130 may be provided at the tub front part 121. A bearing 122a configured to rotatably fix a motor 141 is provided at a rear wall of the tub rear part 122.

The drum 130 may be rotatably provided inside the tub 120 and may accommodate laundry. The drum 130 may include a cylindrical drum body 131, a drum front part 132 provided at the front of the drum body 131, and a drum rear part 133 provided at the rear of the drum body 131. The tub 120 and the drum 130 may be arranged to be inclined with respect to the ground. However, it is also possible for the tub 120 and the drum 130 to be arranged horizontally with respect to the ground.

A through-hole 131a connecting the inside of the drum 130 and the inside of the tub 120, and a lifter 131b for lifting laundry to the top of the drum 130 while the drum 130 rotates may be provided on an inner surface of the drum body 131. An opening 132a for putting laundry into the drum 130 or taking laundry out of the drum 130 may be provided on the drum front part 132. The drum rear part 133 may be connected to a shaft 141a of the motor 141 configured to rotate the drum 130.

The motor 141 may rotate the drum 130. The motor 141 may be included in the driving portion 140. The motor 141 may be disposed on the outside of the tub rear part 122 and connected to the drum rear part 133 through the shaft 141a. The shaft 141a may penetrate the tub rear part 122 and may be rotatably supported by the bearing 122a provided in the tub rear part 122.

The motor 141 may include a stator 142 fixed to the outside of the tub rear part 122, and a rotor 143 configured to rotate and connected to the shaft 141a. The rotor 143 may rotate by magnetic interaction with the stator 142, and the rotation of the rotor 143 may be transmitted to the drum 130 through the shaft 141a. The motor 141 may be a brushless direct current motor (BLDC motor) or a permanent magnet synchronous motor (PMSM) in which a rotation speed thereof is easy to control.

According to various embodiments, the washing machine 10 may further include a pulsator (not shown) configured to rotate independently of the drum 130.

The pulsator may rotate independently of the drum 130 to form a water current inside the drum 130.

According to one embodiment, the pulsator may be powered by the motor 141, or may be powered by a pulsator motor provided separately from the motor 141.

When the pulsator is powered by the motor 141, the motor 141 may be implemented as a dual rotor motor including one stator and two rotors (e.g., an inner rotor and an outer rotor), and one of the two rotors may be connected to the drum 130 and the other thereof may be connected to the pulsator.

The water supply device 150 may supply water to the tub 120 and the drum 130. The water supply device 150 may include a water supply pipe 151 connected to an external water source to supply water to the tub 120, and a water supply valve 152 disposed in the water supply pipe 151. The water supply pipe 151 may be provided on the upper side of the tub 120 and may extend from the external water source to a detergent container 171. Water may flow into the tub 120 through the detergent container 171.

The water supply valve 152 may open or close the water supply pipe 151 in response to an electrical signal from a controller 190. That is, the water supply valve 152 may allow or block the water supply from an external water source to the tub 120. The water supply valve 152 may include a solenoid valve configured to be opened and closed in response to an electrical signal.

The drainage device 160 may discharge water contained in the tub 120 and/or the drum 130 to the outside. The drainage device 160 may include a drainage pipe 161 extending from a bottom of the tub 120 to the outside of the cabinet 100, and a drainage pump 162 provided on the drainage pipe 161. The drainage pump 162 may pump water in the drainage pipe 161 to the outside of the cabinet 100.

The detergent supply portion 170 may supply detergent to the tub 120 and/or the drum 130. The detergent supply portion 170 may include the detergent container 171 provided on the upper side of the tub 120 to store detergent, and a mixing pipe 172 connecting the detergent container 171 to the tub 120. The detergent container 171 may be connected to the water supply pipe 151, and water supplied through the water supply pipe 151 may be mixed with the detergent in the detergent container 171. The mixture of detergent and water may be supplied to the tub 120 through the mixing pipe 172.

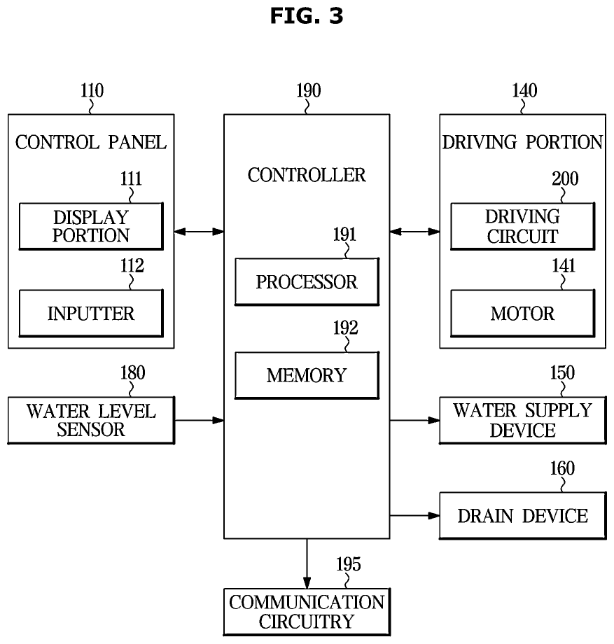

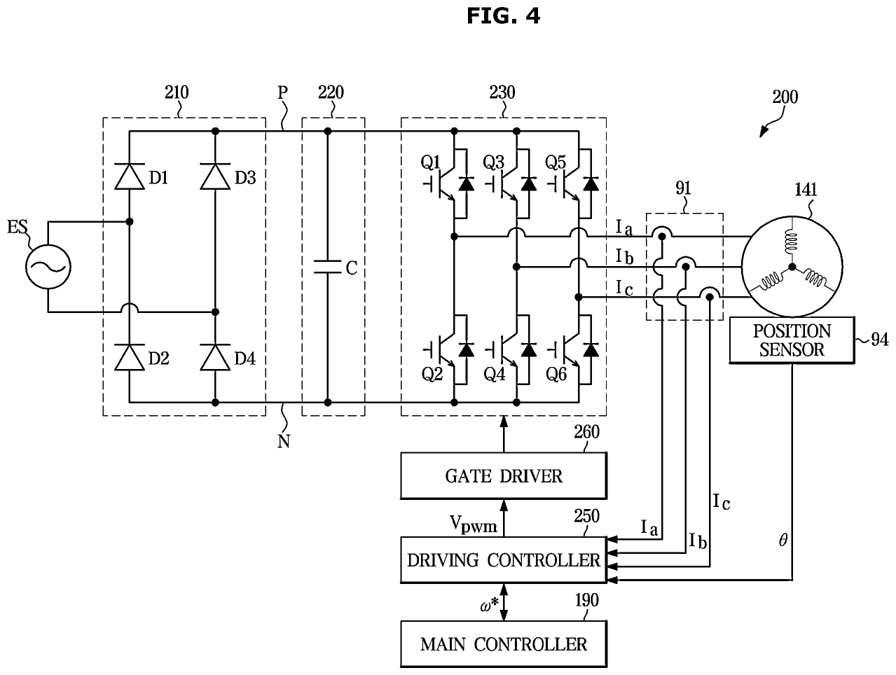

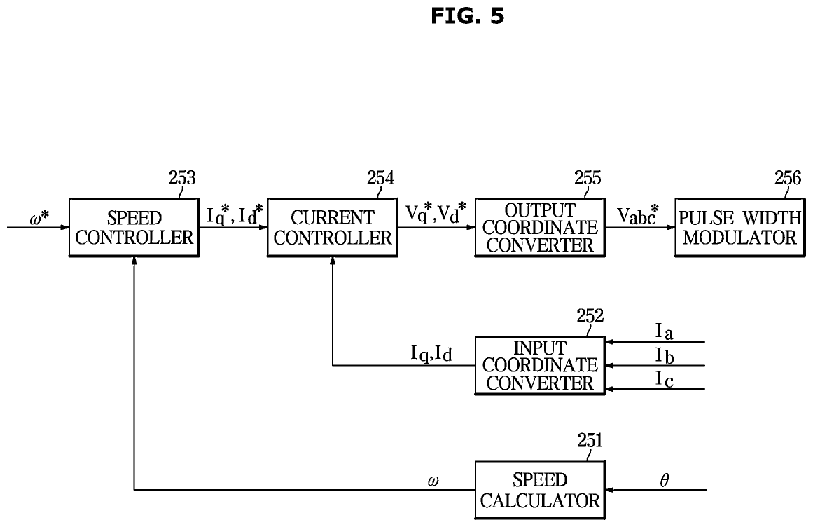

FIG. 3 is a block diagram illustrating a configuration of the washing machine according to one embodiment, FIG. 4 illustrates an example of a driving circuit included in the washing machine according to one embodiment, and FIG. 5 illustrates an example of a driving controller included in the washing machine according to one embodiment.

The washing machine 10 may further include electrical/electronic configurations described below in addition to the mechanical configurations described with reference to FIGS. 1 and 2.

Referring to FIGS. 3, 4, and 5, the washing machine 10 may include the control panel 110, the driving portion 140, the water supply device 150, the drainage device 160, the water level sensor 180, the controller 190, and a communication circuitry 195.

The washing machine 10 may include the control panel 110, the driving portion 140, the water supply valve 152, the drainage pump 162, the water level sensor 180, the controller 190, and/or the communication circuitry 195. The controller 190 may be electrically connected to components of the washing machine 10 and may control the operation of each component.

The control panel 110 may include the display portion 111 provided to display washing settings and/or washing operation information in response to a user input, and the inputter 112 configured to receive a user input. The control panel 110 may provide a user interface for interaction between a user and the washing machine 10. The inputter 112 may include a power button, an operation button, a course selection dial, and a detailed setting button. In addition, the inputter 112 may be provided as a tact switch, a push switch, a slide switch, a toggle switch, a micro switch, or a touch switch.

The display portion 111 may include a screen configured to display various types of information, and an indicator configured to display detailed settings that is selected by a setting button. The display portion 111 may include a liquid crystal display (LCD) panel and/or a light emitting diode (LED).

A washing course of the washing machine 10 may include predetermined process conditions (e.g., washing temperature, number of rinsing times, and spin-drying intensity) according to the type of laundry (e.g., shirt, pants, underwear, and blanket), material (e.g., cotton, polyester, and wool), and amount of laundry. For example, a standard washing course may include process conditions which are generally applied to the laundry. A blanket washing course may include process conditions optimized for washing blankets. The washing course may include various courses such as the standard washing course, a strong washing course, a wool washing course, the blanket washing course, a general clothes washing course, a baby clothes washing course, a towel washing course, a small amount washing course, a boiling washing course, an energy-saving washing course, an outdoor-clothes washing course, a rinsing+spin-drying course, and a spin-drying course.

The driving portion 140 may include the motor 141 and a driving circuit 200. The driving circuit 200 may supply a driving current to the motor 141 to drive the motor 141 in response to a driving signal (motor control signal) of the controller 190. The driving circuit 200 may rectify AC power of an external power source ES to convert the AC power into DC power, and may convert the DC power into driving power in a sinusoidal wave form. The driving circuit 200 may include an inverter configured to output the driving power to the motor 141. The inverter may include a plurality of switching elements, and may open (off) or close (on) the plurality of switches based on a driving signal of the controller 190. The driving current may be supplied to the motor 141 depending on the opening or closing of the switching elements. Additionally, the driving circuit 200 may include a current sensor 91 configured to measure the driving current output from the inverter.

The controller 190 may calculate a rotation speed of the motor 141 based on a rotor electrical angle of the motor 141. The rotor electrical angle may be obtained from a position sensor 94 disposed in the motor 141. For example, the controller 190 may calculate the rotation speed of the motor 141 based on the amount of change in the rotor electrical angle with respect to a sampling time interval. The position sensor (not shown) may be implemented as a Hall sensor, an encoder, or a resolver configured to measure the position of the rotor 143 of the motor 141. In addition, the controller 190 may also calculate the rotation speed of the motor 141 based on a driving current value measured by the current sensor 91.

According to various embodiments, the controller 190 may determine a weight of laundry and whether or not the laundry includes a waterproof cloth based on the driving current value measured by the current sensor 91.

The motor 141 may rotate the drum 130 under the control of the controller 190. The controller 190 may drive the motor 141 to follow a target rotation speed.

Particularly, as illustrated in FIG. 4, the driving circuit 200 may include a rectifier circuit 210 configured to rectify AC power of an external power source ES, a DC link circuit 220 configured to remove ripple of the rectified power and output DC power, an inverter circuit 230 configured to convert the DC power into driving power in the form of a sinusoidal wave and output a driving current Iabc to the motor 141, the current sensor 91 configured to measure the driving currents Ia, Ib, and Ic supplied to the motor 141, a driving controller 250 configured to control the driving power conversion of the inverter circuit 230, and a gate driver 260 configured to turn on/off the switching circuits Q1, Q2, Q3, Q4, Q5 and Q6 included in the inverter circuit 230 based on a driving signal of the driving controller 250.

Further, each motor 141 may be provided with the position sensor 94 configured to measure the position (electrical angle) of the rotor 143 of the motor 141.

The rectifier circuit 210 may include a diode bridge including a plurality of diodes D1, D2, D3 and D4. The diode bridge is provided between a positive terminal P and a negative terminal N of the driving circuit 200. The rectifier circuit 210 may rectify AC power (AC voltage and AC current), in which a magnitude and direction thereof change over time, into power having a constant direction.

The DC link circuit 220 includes a DC link capacitor C configured to store electric energy. The DC link capacitor C is disposed between the positive terminal P and the negative terminal N of the driving circuit 200. The DC link circuit 220 may receive power rectified by the rectifier circuit 210 and may output DC power having a constant magnitude and direction.

The inverter circuit 230 may include three pairs of switching elements Q1 and Q2, Q3 and Q4, and Q5 and Q6 disposed between the positive terminal P and the negative terminal P of the driving circuit 200. Particularly, the inverter circuit 230 may include a plurality of upper switching elements Q1, Q3 and 15 and a plurality of lower switching elements Q2, Q4 and Q6.

The switching elements Q1 and Q2, Q3 and Q4, and Q5 and Q6 may include two switching elements Q1 and Q2, Q3 and Q4, and Q5 and Q6 that are connected in series with each other. The switching elements Q1, Q2, Q3, Q4, Q5 and Q6 included in the inverter circuit 230 may be turned on/off according to the output of the gate driver 260, and three-phase driving currents Ia, Ib and Ic may be supplied to the motor 141 according to the turning on/off of the switching elements Q1, Q2, Q3, Q4, Q5 and Q6.

The current sensor 91 may measure the three-phase driving current (a-phase current, b-phase current, and c-phase current) output from the inverter circuit 230 and output data representing the measured three-phase driving current values (Ia, Ib, Ic: Iabc) to the driving controller 250. In addition, the current sensor 91 may measure only two-phase driving currents among the three-phase driving currents Iabc, and the driving controller 250 may estimate another driving current from the two-phase driving currents.

The position sensor 94 may be disposed in the motor 141, and may measure a position θ of the rotor 143 of the motor 141 (e.g., the rotor electrical angle), and output position data representing the electrical angle θ of the rotor 143. The position sensor 94 may be implemented with a Hall sensor, an encoder, a resolver, or the like.

The gate driver 260 may output a gate signal for turning on/off the plurality of switching circuits Q1, Q2, Q3, Q4, Q5 and Q6 included in the inverter circuit 230 based on the output of the driving controller 250.

The driving controller 250 may be provided separately from the controller 190. For example, the driving controller 250 may include an application specific integrated circuit (ASIC) configured to output a drive signal based on a rotation speed command ù*, a drive current value Iabc, and a rotor position θ. Alternatively, the driving controller 250 may include a memory provided to store a series of commands for outputting a drive signal based on a rotation speed command ù*, a drive current value Iabc, and a rotor position θ, and a processor configured to process a series of commands stored in the memory.

The driving controller 250 may be provided integrally with the controller 190. For example, the driving controller 250 may be implemented as a series of commands for outputting the drive signal based on the rotation speed command ù*, the drive current value Iabc, and the rotor position θ stored in the memory 192 of the controller 190.

The driving controller 250 may receive a motor control signal (e.g., a rotation speed command) from the controller 190, a driving current value Iabc from the current sensor 91, and a rotor position θ of the motor 141 from the position sensor 94. The driving controller 250 may determine a driving current value to be supplied to the motor 141 based on the rotation speed command ù*, the driving current value Iabc, and the rotor position θ, and output a driving signal (PWM signal) for controlling the inverter circuit 230 according to the determined driving current value.

The driving controller 250 may include a speed calculator 251, an input coordinate converter 252, a speed controller 253, a current controller 254, an output coordinate converter 255, and a pulse width modulator 256, as shown in FIG. 5.

The speed calculator 251 may calculate a rotation speed value ù of the motor 141 based on the rotor electrical angle θ of the motor 141. The rotor electrical angle θ may be received from the position sensor 94 disposed in the motor 141. For example, the speed calculator 251 may calculate the rotation speed value ù of the motor 141 based on the amount of change in the electrical angle θ of the rotor 143 based on the sampling time interval.

According to embodiments, when the position sensor 94 is not provided, the speed calculator 251 may calculate the rotation speed value ù of the motor 141 based on the driving current value Iabc measured by the current sensor 91.

The input coordinate converter 252 may convert the three-phase driving current value Iabc into a d-axis current value Id and a q-axis current value Iq (hereinafter referred to as the d-axis current and the q-axis current) based on the rotor electrical angle θ. In other words, the input coordinate converter 252 may perform axis conversion of the a-axis, b-axis, and c-axis of the three-phase driving current value Iabc into the d-axis and the q-axis. The d-axis means an axis in a direction that matches the direction of the magnetic field generated by the rotor of the motor 141, and the q-axis means an axis in a direction that is 90 degrees ahead of the direction of the magnetic field generated by the rotor of the motor 141. 90 degrees means an electrical angle, not a mechanical angle of the rotor, and the electrical angle means an angle converted into 360 degrees from an angle between adjacent N poles of the rotor or an angle between adjacent S poles.

Further, the d-axis current may represent a current component that generates a magnetic field in the d-axis direction in the driving current, and the q-axis current may represent a current component that generates a magnetic field in the q-axis direction in the driving current.

The input coordinate converter 252 may calculate a q-axis current value Iq and a d-axis current value Id from the three-phase driving current value Iabc using a known method.

The speed controller 253 may compare the rotation speed command ù* of the controller 190 with the rotation speed value ù of the motor 141, and output a q-axis current command Iq* and a d-axis current command Id* based on the comparison result. For example, the speed controller 253 may calculate the q-axis current command Iq* and the d-axis current command Id* to be supplied to the motor 141 based on the difference between the rotation speed command ù* and the rotation speed value ù by using proportional integral control (PI control).

The current controller 254 may compare the q-axis current command Iq* and the d-axis current command Id* output from the speed controller 253 with a q-axis current value Iq and a d-axis current value Id output from the input coordinate converter 252, and output a q-axis voltage command Vq* and a d-axis voltage command Vd* based on the comparison result. Particularly, the current controller 254 may determine the q-axis voltage command Vq* based on the difference between the q-axis current command Iq* and the q-axis current value Iq, and may determine the d-axis voltage command Vd* based on the difference between the d-axis current command Id* and the d-axis current value Id, by using proportional integral control (PI control).

The output coordinate converter 255 may convert a dq-axis voltage command Vdq* into a three-phase voltage command (a-phase voltage command, b-phase voltage command, and c-phase voltage command: Vabc*) based on the rotor electrical angle θ of the motor 141.

The output coordinate converter 255 may convert the dq-axis voltage command Vdq* into the three-phase voltage command Vabc* using a known method.

The pulse width modulator 256 may generate a PWM control signal Vpwm for turning on or off the switching circuits Q1, Q2, Q3, Q4, Q5 and Q6 of the inverter circuit 230 from the three-phase voltage command Vabc*. Particularly, the pulse width modulator 256 may perform pulse width modulation (PWM) on the three-phase voltage command Vabc* and output the pulse width modulated PWM signal Vpwm to the gate driver 260.

Accordingly, the driving controller 250 may output a drive signal (PWM signal) to the gate driver 260 based on a motor control signal (e.g., rotation speed command) of the controller 190. In addition, the driving controller 250 may provide the drive current value labc, the dq-axis current value Idq, and the dq-axis current command Idq* to the controller 190.

As mentioned above, the drive circuit 200 may supply a driving current to the motor 141 according to a motor control signal (e.g., rotation speed command and rotation deceleration command) of the controller 190.

The motor 141 may rotate the drum 130 depending on the driving current from the driving circuit 200. For example, the motor 141 may rotate the drum 130 to allow the rotation speed of the drum 130 to follow the rotation speed command output from the controller 190 depending on the driving current.

Further, the motor 141 may decelerate the drum 130 to allow the rotation speed of the drum 130 to follow the rotation deceleration command output from the controller 190 according to the driving current.

The water supply valve 152 may be opened in response to a water supply signal from the controller 190. As the water supply valve 152 opens, water may be supplied to the tub 120 through the water supply pipe 151.

The drainage pump 162 may discharge water to the outside of the cabinet 100 through the drainage pipe 161 in response to a drain signal from the controller 190. Depending on the operation of the drainage pump 162, water contained in the tub 120 may be discharged to the outside of the cabinet 100 through the drainage pipe 161.

The water level sensor 180 may detect the water level of the tub 120. For example, the water level sensor 180 may be installed inside the lower portion of the tub 120. As the water level of the tub 120 rises, a pressure applied to the water level sensor 180 may increase, and accordingly, the water level sensor 180 may detect a frequency that changes according to the water level when the drum 130 rotates.

In one embodiment, the controller 190 may identify the water level of the tub 120 by analyzing the frequency (water level frequency) of an electrical signal corresponding to an input measured from the water level sensor 180.

The controller 190 may include a processor 191 configured to generate a control signal regarding the operation of the washing machine 10, and a memory 192 provided to store a program, an application, an instruction, and/or data for the operation of the washing machine 10. The processor 191 and the memory 192 may be implemented as separate semiconductor devices or may be implemented as a single semiconductor device. In addition, the controller 190 may include a plurality of processors or a plurality of memories. The controller 190 may be disposed at various locations within the washing machine 10. For example, the controller 190 may be included in a printed circuit board provided within the control panel 110.

The processor 191 may include an arithmetic circuit, a memory circuit, and a control circuit. The processor 191 may include one chip or may include multiple chips. In addition, the processor 191 may include one core or may include multiple cores.

The memory 192 may store a program for performing a washing cycle according to a washing course, a program for changing process conditions according to a type of laundry, and data including process conditions according to a washing course. In addition, the memory 192 may store a currently selected washing course and washing settings (e.g., spin-drying mode) based on a user input.

In one embodiment, the memory 192 may store a program including an algorithm for performing a washing cycle according to a washing course and washing settings, an algorithm for identifying whether a waterproof cloth is included, an algorithm for changing a washing cycle according to whether a waterproof cloth is included, etc.

The memory 192 may include a volatile memory such as Static Random Access Memory (S-RAM) and Dynamic Random Access Memory (D-RAM), and a nonvolatile memory such as Read Only Memory (ROM) and Erasable Programmable Read Only Memory (EPROM). The memory 192 may include one memory element or a plurality of memory elements.

The processor 191 may process data and/or signals using a program provided from the memory 192, and transmit a control signal to each component of the washing machine 10 based on the processing result. For example, the processor 191 may process a user input received through the control panel 110. The processor 191 may output a control signal for controlling the display portion 111, the motor 141, the water supply device 150, and the drainage device 160 in response to the user input.

As another example, the processor 191 may use a program provided from the memory 192 to determine the weight of the laundry and whether the laundry includes a waterproof cloth, and further control the operation of the washing machine by considering the proportion of the water trapped in the waterproof cloth to the weight of the laundry.

The processor 191 may control the driving portion 140, the water supply device 150, and the drainage device 160 to perform the washing cycle composed of a washing process, a rinsing process, and a spin-drying process according to predetermined process conditions. In addition, the processor 191 may control the control panel 110 to display washing settings and washing operation information.

Further, the processor 191 may control the communication circuitry 195 to transmit certain information to an external device.

The communication circuitry 195 may transmit data to an external device or receive data from an external device based on the control of the controller 190. For example, the communication circuitry 195 may communicate with a server and/or a user terminal device and/or a home appliance to transmit and receive various types of data.

For the communication, the communication circuitry 195 may establish a direct (e.g., wired) communication channel or a wireless communication channel between external devices (e.g., a server, a user terminal device and/or a home appliance), and support the performance of the communication through the established communication channel. According to one embodiment, the communication circuitry 195 may include a wireless communication module (e.g., a cellular communication module, a short-range wireless communication module, or a global navigation satellite system (GNSS) communication module) or a wired communication module (e.g., a local area network (LAN) communication module, or a power line communication module). Among these communication modules, the corresponding communication module may communicate with an external device through a first network (e.g., a short-range wireless communication network such as Bluetooth, wireless fidelity (Wi-Fi) direct, or infrared data association (IrDA)) or a second network (e.g., a long-range wireless communication network such as a legacy cellular network, a 5G network, a next-generation communication network, the Internet, or a computer network (e.g., LAN or WAN). These various types of communication modules may be integrated as one component (e.g., a single chip) or implemented as a plurality of separate components (e.g., multiple chips).

According to various embodiments, the communication circuitry 195 may establish communication with a user terminal device through a server.

According to various embodiments, the communication circuitry 195 may include a Wi-Fi module and may perform communication with an external server and/or user terminal device based on establishing communication with an access point (AP) within the house.

The configuration of the washing machine 10 is described in the above-description, but the washing machine 10 may further include various configurations within the scope of conventional technology.

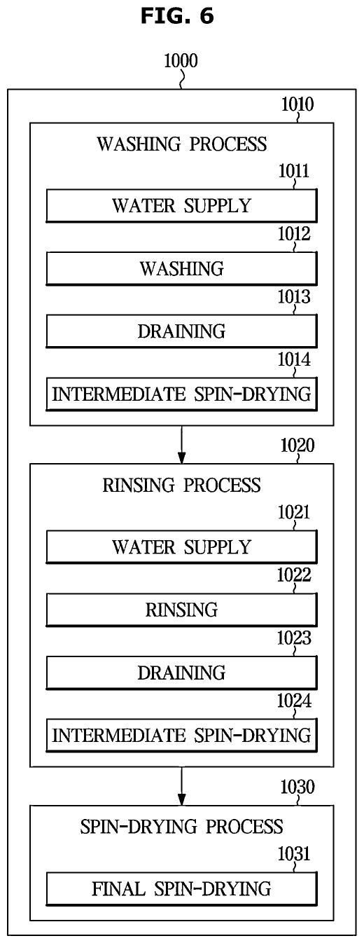

FIG. 6 illustrates an example of a washing cycle of the washing machine according to one embodiment.

Referring to FIG. 6, the washing machine 10 may sequentially perform a washing process (1010), a rinsing process (1020), and a spin-drying process (1030) based on a user input to start a washing cycle (1000).

That is, the washing cycle (1000) may include the washing process (1010), the rinsing process (1020), and the spin-drying process (1030).

Through the washing process (1010), laundry may be washed. Particularly, foreign substances attached to the laundry may be separated by the chemical action of the detergent and/or mechanical action such as falling.

The washing process (1010) may include water supply (1011) for supplying water to the tub 120, washing (1012) for washing laundry by rotating the drum 130 at a low speed, draining (1013) for discharging water contained in the tub 120, and intermediate spin-drying (1014) for separating water from the laundry by rotating the drum 130 at a high speed.

For the washing (1012), the controller 190 may control the driving circuit 200 to rotate the motor 141 in a forward direction or reverse direction. By the rotation of the drum 130, laundry may fall from the upper side to the lower side of the drum 130, and the laundry may be washed by the falling.

For the intermediate spin-drying (1014), the controller 190 may control the driving circuit 200 to rotate the motor 141 at a high speed. By the high-speed rotation of the drum 130, water may be separated from the laundry contained in the drum 130 and discharged to the outside of the washing machine 10.

During the intermediate spin-drying (1014), the rotation speed of the drum 130 may be increased stepwise. For example, the controller 190 may control the driving circuit 200 to rotate the motor 141 at a first rotation speed. While the motor 141 rotates at the first rotation speed, the controller 190 may control the motor 141 to increase the rotation speed of the motor 141 to a second rotation speed based on a change in the driving current of the motor 141. While the motor 141 rotates at the second rotation speed, the controller 190 may control the motor 141 to increase the rotation speed of the motor 141 to a third rotation speed or to reduce the rotation speed of the motor 141 to the first rotation speed based on a change in the driving current of the motor 141.

Through the rinsing process (1020), laundry may be rinsed. Particularly, detergent or foreign substances left on the laundry may be washed away by water.

The rinsing process (1020) may include water supply (1021) that supplies water to the tub 120, rinsing (1022) that drives the drum 130 to rinse laundry, draining (1023) that discharges water contained in the tub 120, and intermediate spin-drying (1024) that drives the drum 130 to separate water from laundry.

The water supply (1021), the draining (1023), and the intermediate spin-drying (1024) of the rinsing process (1020) may be the same as the water supply (1012), the draining (1014), and the intermediate spin-drying (1014) of the washing process (1010), respectively. During the rinsing process (1020), the water supply (1021), the rinsing (1022), the draining (1023), and the intermediate spin-drying (1024) may be performed once or multiple times.

Through the spin-drying process (1030), laundry may be spin-dried. Particularly, water may be separated from laundry by the high-speed rotation of the drum 130, and the separated water may be discharged to the outside of the washing machine 10.

The spin-drying process (1030) may include final spin-drying (1031) that separates water from the laundry by rotating the drum 130 at a high speed. Due to the final spin-drying (1031), the last intermediate spin-drying (1024) of the rinsing process (1020) may be omitted.

For the final spin-drying (1031), the controller 190 may control the driving circuit 200 to rotate the motor 141 at a high speed. By the high-speed rotation of the drum 130, water may be separated from the laundry contained in the drum 130 and discharged to the outside of the washing machine 10. In addition, the rotation speed of the motor 141 may be increased stepwise.

Because the operation of the washing machine 10 is terminated by the final spin-drying (1031), an execution time of the final spin-drying (1031) may be longer than an execution time of the intermediate spin-drying process (1015 or 1024).

As mentioned above, the controller 190 may sequentially perform the washing process (1010), the rinsing process (1020), and the spin-drying process (1030).

The controller 190 may perform spin-drying by rotating the drum 130 and the pulsator at a high speed one or more times during the washing process (1010), the rinsing process (1020), and the spin-drying process (1030).

The drum 130 rotates at a high speed, and thus when the center of gravity of the laundry and the drum 130 deviates from the rotation axis of the drum 130 (when weight imbalance occurs), the tub 120 may vibrate significantly together with the drum 130. In some cases, the vibration of the tub 120 may cause damage to the washing machine 10.

The imbalance of the drum 130 is generally caused by laundry received in the drum 130, and it is known that the imbalance of the drum 130 is caused by tangled laundry, etc.

Particularly, a waterproof cloth, through which water is not permeable or does not penetrate, in the laundry may cause significant imbalance in the drum 130. For example, the waterproof cloth may trap water like a water bag, and the waterproof cloth may cause weight imbalance inside the drum 130 while the drum 130 rotates at a high speed.

To detect a waterproof cloth causing the imbalance, the controller 190 may add a new process to the washing cycle (1000).

For example, the washing cycle (1000) may further include a laundry measurement operation to measure a weight of the laundry prior to the water supply (1011).

Additionally, separate processes may be added to the washing cycle (1000) depending on the type of washing setting and washing course.

For example, before the washing cycle (1000) begins, weight detection and first driving current detection processes may be added, and after the washing process (1010) ends or the rinsing process ends, a second driving current detection process may be added.

The controller 190 may determine whether the laundry is not draining water and is retaining water based on the measured current value and the weight of the laundry. In addition, the controller may determine whether a waterproof cloth is included based on the fact that when the laundry is retaining water, there is a high possibility that the laundry contains a waterproof cloth.

The controller 190 may reduce the rotation speed of the drum 130 for the spin-drying in response to detection of the waterproof cloth or may output a waterproof cloth containing notification on the display to notify a user of the notification.

Hereinafter the operation of the controller 190 for detecting a waterproof cloth is described.

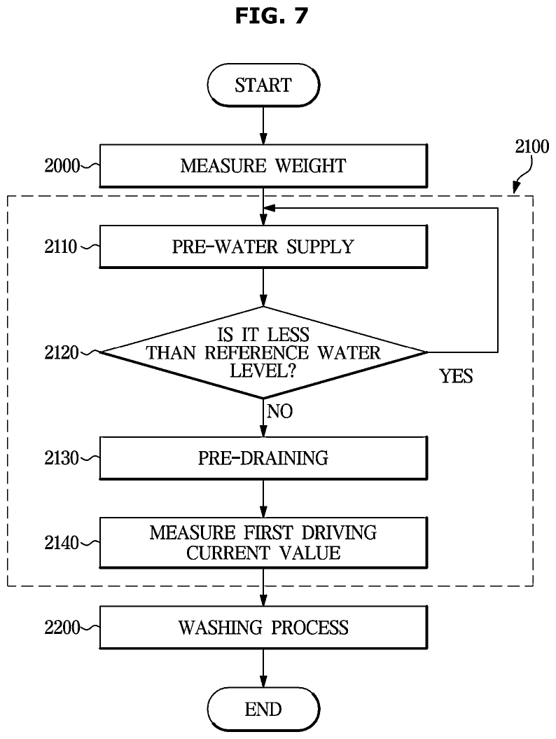

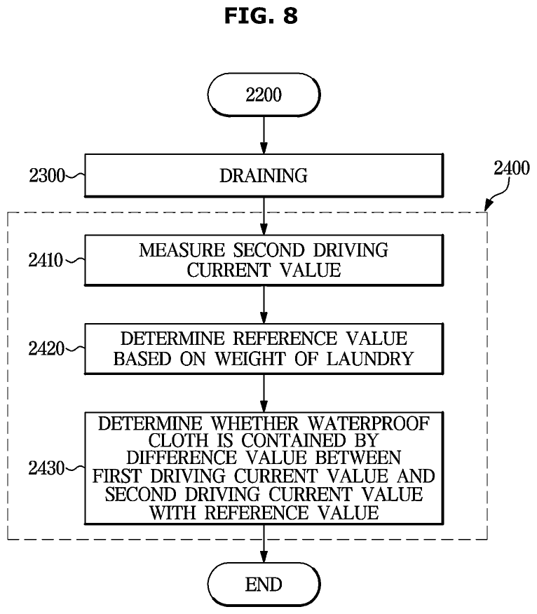

FIG. 7 is a flowchart illustrating a method for the washing machine according to one embodiment to detect a first driving current before performing the washing cycle, and FIG. 8 is a flowchart illustrating a method for the washing machine according to one embodiment to detect a second driving current and determine whether a waterproof cloth is included.

Referring to FIG. 7, as described above, the controller 190 may perform the weight measurement (2000) and the first current detection process (2100) before the washing cycle (1000) is performed.

The controller 190 may control the driving portion 140 to repeatedly turn on/off the motor 141 to perform the weight measurement (2000), and may measure a load (weight of laundry) inside the drum 130 based on a counter electromotive force value that is generated when the motor 141 is turned off. As another example, the controller 190 may provide the driving portion 140 with a target speed command to rotate the drum 130 at a first target speed, and may measure the load (weight of laundry) inside the drum 130 based on a time taken for the drum 130 to reach the first target speed. In addition, the controller 190 may store the measured weight of laundry in the memory 192.

The controller 190 may perform pre-water supply (2110) and pre-draining (2130) to measure a first driving current value in a state in which the laundry accommodated in the drum 130 is wet.

The controller 190 may determine whether a water level of the tub 120 reaches a reference water level after the pre-water supply (2120). The reference water level refers to a water level that may create a wet state for laundry contained in the drum 130.

The controller 190 may determine the reference water level based on the measured weight of the laundry. Particularly, the reference water level may be determined in proportion to the measured weight of the laundry.

For example, when the measured weight of the laundry is 5 kg, the reference water level may be determined as a, and when the measured weight of the laundry is 10 kg, the reference water level may be determined as b, which is twice a.

According to various embodiments, the memory 192 may store data regarding the reference water level required to perform the pre-draining.

After the pre-draining is completed, the controller 190 may measure the first driving current value (2140).

The controller 190 may measure the first driving current value while rotating the drum 130 after the pre-draining is completed. For example, the controller 190 may control the driving portion 140 to rotate the drum 130 to a target rotation speed, and may measure the first driving current value by calculating an average of driving current values measured from the current sensor 91 while the drum 130 reaches the target rotation speed. In addition, the controller 190 may store the measured first driving current value in the memory 192.

The controller 190 may perform the washing process (2200) after the first current detection process (2100) is completed.

Referring to FIG. 8, as described above, the controller 190 may perform draining (2300) and waterproof cloth detection process (2400) after the washing process (1010) is completed. Hereinafter in the present embodiment, it is described that the draining (2300) and the waterproof cloth detection process (2400) are performed after the washing process is completed, but this is not limited thereto. Alternatively, the draining (2300) and the waterproof cloth detection process (2400) may be performed even after the rinsing process (1020) is completed.

The controller 190 may perform the draining (2300) to discharge water contained in the drum 130 after the washing process (1010).

The controller 190 may measure a second driving current value after the draining is completed (2410).

The controller 190 may measure the second driving current value while rotating the drum 130 after the draining is completed. For example, the controller 190 may control the driving portion 140 to rotate the drum 130 to a target rotation speed, and may measure the second driving current value by calculating an average of driving current values measured from the current sensor 91 while the drum 130 reaches the target rotation speed. In addition, the controller 190 may measure the second driving current value multiple times.

The controller 190 may store at least one measured second driving current value in the memory 192.

The controller 190 may compare a difference value (hereinafter, “difference value”) between the measured first driving current and second driving current with a reference value to determine whether a waterproof cloth is included in the laundry (2430). For example, in response to the difference value being less than the reference value, it may be determined that a waterproof cloth is not included, and in response to the difference value being greater than or equal to the reference value, it may be determined that a waterproof cloth is included.

In addition, the controller 190 may determine whether a waterproof cloth is included by comparing the difference value between the first driving current value and each second driving current value with the reference value in response to the second driving current value being measured multiple times. For example, in response to at least one of the difference values between the first driving current value and each second driving current value being greater than or equal to the reference value, it may be determined that a waterproof cloth is included.

The controller 190 may determine the reference value based on the weight of the laundry (2420). Particularly, the controller 190 may determine the reference value in proportion to a weight value of the laundry.

For example, when the weight of the laundry is 5 kg, the reference value may be set to a′, and when the weight of the laundry is 40 kg, the reference value may be set to b′, which is three times a′.

This is because the possibility of causing weight imbalance inside the drum 130 varies depending on the proportion of the amount of water trapped by the waterproof cloth to the weight of the laundry after the washing process (1010).

The memory 192 may store the weight of the laundry by dividing the weight into stages. For example, it may store a stage 1 when the weight of the laundry is 0 kg or more but less than 5 kg, a stage 2 when the weight of the laundry is 5 kg or more but less than 10 kg, and a stage 7 when the weight of the laundry is 30 kg or more but less than 35 kg. In addition, the memory 192 may store a corresponding reference value for each stage. For example, in the case of stage 1, in which the weight of the laundry is light, the reference value may be stored as c′, and in the case of stage 7, in which the weight of the laundry is heavy, the reference value may be stored as d′, which is three times c′. The controller 190 may detect a waterproof cloth more efficiently by changing waterproof cloth detection criteria according to the weight of the laundry.

In addition, in response to a determination that a waterproof cloth is included in the laundry, the controller 190 may control the driving portion 140 to reduce the rotation speed and control the display portion to display a notification to a user.

In response to a determination that the waterproof cloth is not contained in the laundry, the controller 190 may perform the rinsing process (1020) or the spin-drying process (1030) according to the washing cycle (1000).

Meanwhile, the disclosed embodiments may be embodied in the form of a recording medium storing instructions executable by a computer. The instructions may be stored in the form of program code and, when executed by a processor, may generate a program module to perform the operations of the disclosed embodiments. The recording medium may be embodied as a computer-readable recording medium.

The computer-readable recording medium includes all kinds of recording media in which instructions which can be decoded by a computer are stored. For example, there may be a Read Only Memory (ROM), a Random Access Memory (RAM), a magnetic tape, a magnetic disk, a flash memory, and an optical data storage device.

While the present disclosure has been particularly described with reference to exemplary embodiments, it should be understood by those of skilled in the art that various changes in form and details may be made without departing from the spirit and scope of the present disclosure.

1. A washing machine comprising:
a drum that is rotatable while accommodated inside a tub;
a driving circuit configured to supply a driving current to a motor to rotate the drum;
a current sensor configured to detect the driving current; and
a controller configured to control the drum, the driving circuit, and the current sensor,
wherein the controller is configured to determine whether laundry in the drum contains a waterproof item based on a weight value of the laundry and a difference value between a first driving current value detected by the current sensor before a washing process and a second driving current value detected by the current sensor after the washing process.

2. The washing machine of claim 1, wherein
the controller is configured to:
determine that the laundry in the drum contains no waterproof item based on the difference value being less than a reference value; and
determine that the laundry in the drum contains the waterproof item based on the difference value being greater than or equal to the reference value.

3. The washing machine of claim 2, wherein
the controller is configured to determine the reference value based on the weight value of the laundry.

4. The washing machine of claim 3, wherein
the reference value is proportional to a weight of the laundry.

5. The washing machine of claim 1, wherein
the controller is configured to perform pre-water supply and pre-draining before measuring the first driving current value.

6. The washing machine of claim 5, further comprising:
a water level sensor configured to detect a water level of the tub,
wherein the controller is configured to perform additional water supply to a reference water level in response to the water level of the tub being less than the reference water level after the pre-water supply.

7. The washing machine of claim 1, wherein
the controller is configured to measure the second driving current value after the washing process and draining are completed.

8. The washing machine of claim 7, wherein
the controller is configured to measure the second driving current value multiple times and configured to determine whether the waterproof item is contained in the laundry in the drum based on each of the measured second driving current values.

9. The washing machine of claim 1, further comprising:
a display configured to display washing settings and washing operation information,
wherein the controller is configured to control the display to display a notification to a user in response to a determination that the waterproof item is contained in the laundry in the drum.

10. A control method of a washing machine comprising:
measuring a first driving current value while rotating a drum before a washing process;
measuring a second driving current value while rotating the drum after the washing process; and
determining whether laundry in the drum contains a waterproof item based on a weight value of the laundry and a difference value between the first driving current value and the second driving current value.

11. The control method of the washing machine of claim 10, wherein
the determining comprises: determining that the laundry in the drum contains no waterproof item based on the difference value being less than a reference value; and determining that the laundry in the drum contains no waterproof item based on the difference value being greater than or equal to the reference value.

12. The control method of the washing machine of claim 11, wherein
the determining comprises determining the reference value based on the weight value of the laundry.

13. The control method of the washing machine of claim 12, wherein
the reference value is proportional to a weight of the laundry.

14. The control method of the washing machine of claim 10, wherein
measuring the first driving current value comprises performing pre-water supply and pre-draining before measuring the first driving current value.

15. The control method of the washing machine of claim 14, wherein
measuring the first driving current value comprises performing additional water supply to a reference water level in response to a water level of a tub being less than the reference water level after the pre-water supply.

16. The control method of the washing machine of claim 10, wherein
measuring the second driving current value comprises measuring the second driving current value after the washing process and draining are completed.

17. The control method of the washing machine of claim 16, further comprising,
measuring the second driving current value multiple times and
determining whether the waterproof item is contained in the laundry in the drum based on each of the measured second driving current values.

18. The control method of the washing machine of claim 10, further comprising, in response to a determination that the waterproof item is contained in the laundry in the drum, displaying a notification to a user of corresponding information to the determination.
